(19) United States
(12) Patent Application Publication
(10) Pub. No.: US 2020/0120792 A1
(43) Pub. Date: Apr. 16, 2020

(54) BACKLIGHT PLATE AND DISPLAY DEVICE

(71) Applicant: Wuhan China Star Optoelectronics Technology Co., Ltd., Wuhan (CN)

(72) Inventor: Bingchuan ZHANG, Wuhan (CN)

(73) Assignee: Wuhan China Star Optoelectronics Technology Co., Ltd., Wuhan (CN)

(21) Appl. No.: 16/316,053

(22) PCT Filed: Sep. 11, 2018
(86) PCT No.: PCT/CN2018/104924

§ 371 Date: Jan. 8, 2019

(30) Foreign Application Priority Data
Aug. 23, 2018 (CN) 201810968697.X

(51) Int. Cl. H05K 1/02; H05K 1/14

(52) U.S. Cl. CPC H05K 1/0281; H05K 2201/056; H05K 2201/10128; H05K 1/147

(57) ABSTRACT

This disclosure provides a backlight plate and a display device, wherein the backlight plate comprises a body and a carrier connected to the body, and at least one side of the carrier closed to the bending area of the flexible printed circuit board is in a curved shape, and the curved shape is matched with a bending shape of the bending area of the flexible printed circuit board, and the carrier is configured to sustain the bending area of the flexible printed circuit board.

### BACKGROUND

### 1. Field of Invention

The present disclosure relates to the field of display technology, and more particularly to a backlight plate and a display device.

### 2. Description of the Prior Art

Along with developments of display devices, display devices with narrow border are getting more and more popular.

Distances between a flexible printed circuit board being bended and an edge of a display module should be controlled to realize the narrow border of display devices. As shown in FIG. 1, A smaller distances X from the flexible printed circuit board 2 to the edge of the display module 3 makes a narrower border of the display devices. However, the smaller value of the distance X brings a greater stress on the flexible printed circuit board 2, which may make the flexible printed circuit 2 as shown in FIG. 1 be deformed, or even be cracked.

### SUMMARY

An object of the present disclosure is to provide a backlight plate and a display device, which can improve a bending performance of the display device.

The present disclosure provides a backlight plate for utilizing in a flexible printed circuit board having a bending area, which includes: a body and a sustaining part connected to the body.

At least one side of the sustaining part closed to the bending area of the flexible printed circuit board has a curved shape, and the curved shape is matched with a bending shape of the bending area of the flexible printed circuit board, and the sustaining part is configured to sustain the bending area of the flexible printed circuit board.

The body and the sustaining part are formed integrally. A height of the sustaining part is greater than a height of the body.

In an embodiment of the present disclosure, a radius of curvature of the curved shape of the sustaining part ranges from 0.4 millimeters to 0.6 millimeters.

In an embodiment of the present disclosure, a height difference of the sustaining part and the body ranges from 0.23 millimeters to 0.25 millimeters.

In an embodiment of the present disclosure, a height of the sustaining part ranges from 1 millimeter to 1.1 millimeters.

The present disclosure provides a backlight plate for utilizing in a flexible printed circuit board having a bending area, which includes: a body and a sustaining part connected to the body.

At least one side of the sustaining part closed to the bending area of the flexible printed circuit board has a curved shape, and the curved shape is matched with a bending shape of the bending area of the flexible printed circuit board, and the sustaining part is configured to sustain the bending area of the flexible printed circuit board.

In an embodiment of the present disclosure, the body and the sustaining part are formed integrally.

In an embodiment of the present disclosure, a radius of curvature of the curved shape of the sustaining part ranges from 0.4 millimeters to 0.6 millimeters.

In an embodiment of the present disclosure, a height of the sustaining part is greater than a height of the body.

In an embodiment of the present disclosure, a height difference of the sustaining part and the body ranges from 0.23 millimeters to 0.25 millimeters.

In an embodiment of the present disclosure, a height of the sustaining part ranges from 1 millimeter to 1.1 millimeters.

The present disclosure further provides a display device, which includes: a backlight plate, a display panel and a flexible printed circuit board.

The display panel is disposed on the backlight plate.

The flexible printed circuit board includes a bending area, and the bending area of the flexible printed circuit board is bended toward the backlight plate for attaching the flexible printed circuit board to a side of the backlight plate away from the display panel.

The backlight plate includes a body and a sustaining part connected to the body, and at least one side of the sustaining part closed to the bending area of the flexible printed circuit board has a curved shape, and the curved shape is matched with a bending shape of the bending area of the flexible printed circuit board, and the sustaining part is configured to sustain the bending area of the flexible printed circuit board.

In an embodiment of the present disclosure, the body and the sustaining part are formed integrally.

In an embodiment of the present disclosure, a radius of curvature of the curved shape of the sustaining part ranges from 0.4 millimeters to 0.6 millimeters.

In an embodiment of the present disclosure, a height of the sustaining part is greater than a height of the body.

In an embodiment of the present disclosure, a height difference of the sustaining part and the body ranges from 0.23 millimeters to 0.25 millimeters.

In an embodiment of the present disclosure, a height of the sustaining part ranges from 1 millimeter to 1.1 millimeters.

The backlight plate and the display device of the present disclosure can improve the bending performance of the display device by setting at least one side of the sustaining part closed to the bending area of the flexible printed circuit board as a curved shape.

### BRIEF DESCRIPTION OF DRAWINGS

Aforementioned contents of the present disclosure will be better understood with reference to the following description, and accompanying figures.

FIG. 1 is a structural schematic diagram of a conventional display device.

FIG. 2 is a structural schematic diagram of a display device according to the present disclosure.

FIG. 3 is a structural schematic diagram of a backlight plate according to the present disclosure.

### DETAILED DESCRIPTION OF PREFERRED EMBODIMENTS

The following description of each embodiment with reference to the accompanying drawings is used to exemplify a specific embodiment which may be carried out in the present disclosure. Directional terms mentioned in the present disclosure, such as “top”, “bottom”, “front”, “back”, “left”, “right”, “inside”, “outside”, “side” etc., are only used with reference to the orientation of the accompanying drawings. Therefore, the used directional terms are intended to illustrate, but not to limit, the present disclosure. Examples of the described embodiments are given in the accompanying drawings, wherein the identical or similar reference numerals constantly denote the identical or similar elements or elements having the identical or similar functions.

Descriptions in the specification referred to “embodiment” mean that a particular feature, structure, or characteristic described in connection with the embodiment is included in at least one embodiment. Thus, appearances of the phrases “embodiment” in places throughout the specification are may be combined in any suitable manner in one or more embodiments. Thus, the particular features, structures, or characteristics illustrated or described in connection with one embodiment may be combined, in whole or in part, with the features structures, or characteristics of one or more other embodiments without limitation. Such modifications and variations are intended to be included within the scope of the present invention.

The present disclosure provides a display device. As shown in FIG. 2, FIG. 2 is a structural schematic diagram of the display device according to the present disclosure. The display device 1 includes a backlight plate 11, a display panel 12, and a flexible printed circuit board 13.

The display panel 12 is disposed on the backlight plate 11. The display panel 12 includes an array substrate 121 and a color filter substrate 122 disposed on the array substrate 121. And, a plurality of thin-film transistors are disposed on the array substrate 121. The color filter substrate 122 may include a glass substrate, a plurality of black matrixes, a color layer and a protective layer and so on, for implementing color display.

The flexible printed circuit board 13 can be formed by bonding polyimides, copper foils and adhesives. The flexible printed circuit board 13 can be a single side board, a double-side board, a slice board and a rigid-flex printed circuit board. The flexible printed circuit board 13 includes a bending area 131 making the flexible printed circuit board 13 bended. As shown in FIG. 2, the bending area 131 of the flexible printed circuit board 13 is bended toward the backlight plate 11 for attaching the flexible printed circuit board 13 to a side of the backlight plate 11 away from the display panel 12. If a radius of curvature of the bending area 131 of the flexible printed circuit board 13 is smaller, stress distribution of the bending area 131 of the flexible printed circuit board 13 will be concentrated making the bending area 131 be deformed or even be broken, and making the display panel 12 connected to the bending area 131 be bended.

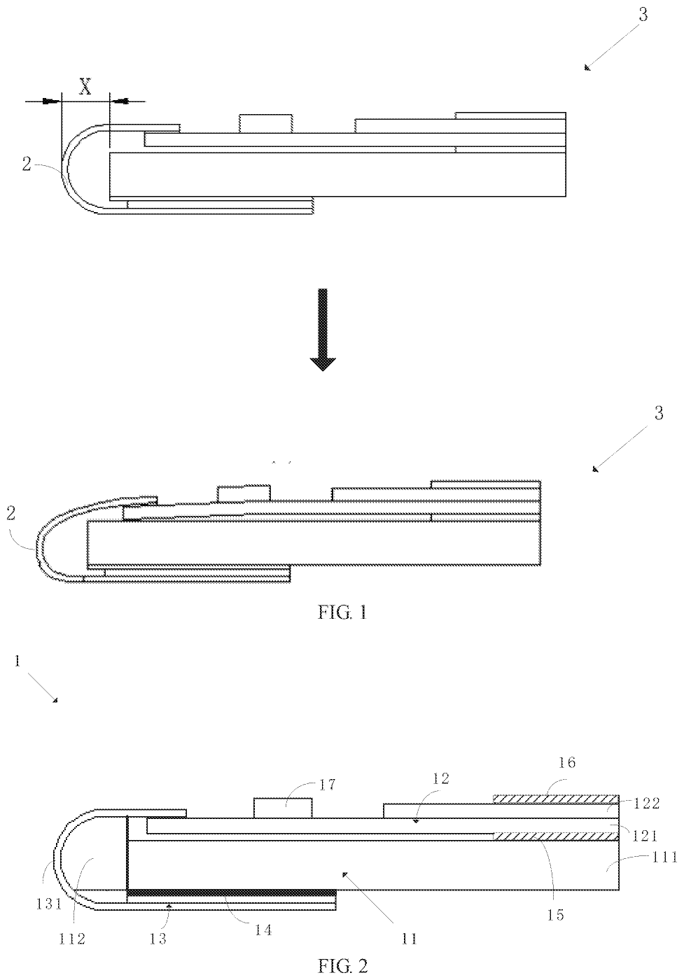

In one embodiment, a gel layer 14 shown in FIG. 1 can be disposed between the flexible printed circuit board 13 and the backlight plate 11 in order to fix the flexible printed circuit 13 on the backlight plate 11. The gel layer 14 can be composed by anisotropic conductive films. And, the anisotropic conductive films are composed by gels, conductive particles and protective films. In addition, the conductive particles play a role of conducting medium when the conductive particles are broken under thermal-pressing.

According to some embodiments of the present disclosure, a shape of the backlight plate 11 is improved to sustain the bending area 131 of the flexible printed circuit board 13. As shown in FIG. 2, the backlight board 11 includes a body 111 and a sustaining part 112 connected to the body 111. And, the body 111 is in a cuboid shape and the body 111 is configured to sustain a polarizer, a display panel and other structures thereon. At least one side of the sustaining part 112 closed to the bending area 131 of the flexible printed circuit board 13 has a curved shape, and the curved shape is matched with a bending shape of the bending area 131 of the flexible printed circuit board 13. According to an embodiment of the present disclosure, the body 111 and the sustaining part 112 are formed integrally.

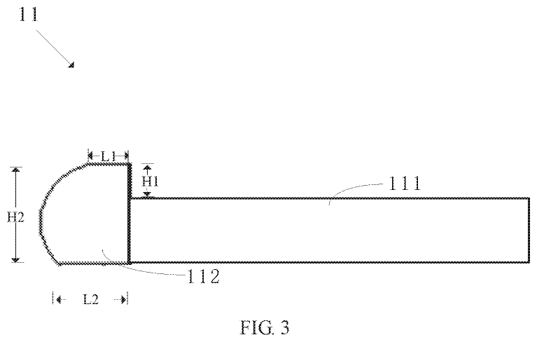

Specifically, as shown in FIG. 2, when the bending area 131 of the flexible printed circuit board 13 is bended toward the backlight plate 11, a part thereof is in a flat state, and another part thereof is in a bending state. Correspondingly, as shown in FIG. 3, a part of side of the sustaining part 112 closed to the bending area 131 of the flexible printed circuit board 13 has a curved shape, and another part has a flat shape. And, a length of a plane on an upper portion of the sustaining part 112 ranges from 0.4 millimeters to 0.5 millimeters. A length of a plane on a bottom portion of the sustaining part 112 ranges from 0.55 millimeters to 0.65 millimeters. According to an embodiment of the present disclosure, a radius of curvature of the curved shape of the sustaining part 112 ranges from 0.4 millimeters to 0.6 millimeters.

According to the embodiment of the present disclosure, as shown in FIG. 2, an end of the flexible printed circuit board 13 is disposed on the display panel 12, and the display panel 12 is disposed on the body 111 of the backlight plate 11. A height of the sustaining part is set greater than a height of the body 111 to avoid a horizontal part of the bending area of the flexible printed circuit board 13 closed to the display panel 12 being suspended. According to an embodiment of the present disclosure, as shown in FIG. 3, the height H2 of the sustaining part 112 ranges from 1 millimeter to 1.1 millimeters. A height difference H1 between the sustaining part 112 and the body 111 ranges from 0.23 millimeters to 0.25 millimeters.

In conclusion, the sustaining part 112 can be attached to the bending area 131 of the flexible printed circuit board 13 perfectly, when the bending area 131 of the flexible printed circuit board 13 is bended toward the backlight plate 11. The sustaining part 112 can sustain the bending area 131 of the flexible printed circuit board 13 for sharing stresses exerted on the bending area 131 of the flexible printed circuit board 13 and avoiding the display panel 12 being bended.

According to some embodiments of the present disclosure, as shown in FIG. 2, a first polarizer 15 is disposed between the backlight plate 11 and the display panel 12, and further, a second polarizer 16 is disposed on the display panel 12. And, lights vibrating in a specific direction are passed as a result of coordination of the first polarizer 15 and the second polarizer 16. A driver chip 17 is disposed on the display panel 12 to control display effects of the display device 1.

The present disclosure provides a backlight plate and a display device which can improve the bending performance of the display device by setting at least one side of the sustaining part closed to the bending area of the flexible printed circuit board as a curved shape.

It should be understood that the specific embodiments described herein are only for explaining the present disclosure and are not intended to limit the present invention. This invention is not limited to the foregoing description of the disclosed embodiments. Various changes and modifications can be made to the invention in light of the above detailed description by those skilled in the art. These changes and modifications are possible within the scope of the invention as defined by the following claims.

What is claimed is:

1. A backlight plate for utilizing in a flexible printed circuit board having a bending area, comprising:
a body and a sustaining part connected to the body;
wherein at least one side of the sustaining part closed to the bending area of the flexible printed circuit board has a curved shape, and the curved shape is matched with a bending shape of the bending area of the flexible printed circuit board, and the sustaining part is configured to sustain the bending area of the flexible printed circuit board;
wherein the body and the sustaining part are formed integrally;
wherein a height of the sustaining part is greater than a height of the body.

2. The backlight plate as claimed in claim 1, wherein a radius of curvature of the curved shape of the sustaining part ranges from 0.4 millimeters to 0.6 millimeters.

3. The backlight plate as claimed in claim 1, wherein a height difference of the sustaining part and the body ranges from 0.23 millimeters to 0.25 millimeters.

4. The backlight plate as claimed in claim 1, wherein a height of the sustaining part ranges from 1 millimeter to 1.1 millimeters.

5. A backlight plate for a flexible printed circuit board having a bending area, comprising:
a body and a sustaining part connected to the body;
wherein at least one side of the sustaining part closed to the bending area of the flexible printed circuit board has a curved shape, and the curved shape is matched with a bending shape of the bending area of the flexible printed circuit board, and the sustaining part is configured to sustain the bending area of the flexible printed circuit board.

6. The backlight plate as claimed in claim 5, wherein the body and the sustaining part are formed integrally.

7. The backlight plate as claimed in claim 5, wherein a radius of curvature of the curved shape of the sustaining part ranges from 0.4 millimeters to 0.6 millimeters.

8. The backlight plate as claimed in claim 5, wherein a height of the sustaining part is greater than a height of the body.

9. The backlight plate as claimed in claim 8, wherein a height difference of the sustaining part and the body ranges from 0.23 millimeters to 0.25 millimeters.

10. The backlight plate as claimed in claim 5, wherein a height of the sustaining part ranges from 1 millimeter to 1.1 millimeters.

11. A display device, comprising:
a backlight plate, a display panel and a flexible printed circuit board;
wherein the display panel is disposed on the backlight plate;
wherein the flexible printed circuit board comprises a bending area, and the bending area of the flexible printed circuit board is bended toward the backlight plate for attaching the flexible printed circuit board to a side of the backlight plate away from the display panel;
wherein the backlight plate comprises a body and a sustaining part connected to the body, and at least one side of the sustaining part closed to the bending area of the flexible printed circuit board has a curved shape, and the curved shape is matched with a bending shape of the bending area of the flexible printed circuit board, and the sustaining part is configured to sustain the bending area of the flexible printed circuit board.

12. The display device as claimed in claim 11, wherein the body and the sustaining part are formed integrally.

13. The display device as claimed in claim 11, wherein a radius of curvature of the curved shape of the sustaining part ranges from 0.4 millimeters to 0.6 millimeters.

14. The display device as claimed in claim 11, wherein a height of the sustaining part is greater than a height of the body.

15. The display device as claimed in claim 14, wherein a height difference of the sustaining part and the body ranges from 0.23 millimeters to 0.25 millimeters.

16. The display device as claimed in claim 11, wherein a height of the sustaining part ranges from 1 millimeter to 1.1 millimeters.
